(19) United States
(12) Patent Application Publication
(10) Pub. No.: US 2005/0003590 A1
(43) Pub. Date: Jan. 6, 2005

(54) Method for defining a source and a drain and a gap inbetween

(76) Inventors: Martin Hillebrand Blees, Eindhoven (NL); Marcel Rene Boehmer, Singapore (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/497,926

(22) PCT Filed: Nov. 25, 2002
(86) PCT No.: PCT/IB02/05036

(30) Foreign Application Priority Data
Dec. 6, 2001 (EP) 01204703.1

(51) Int. Cl. H01L 21/00; H01L 21/84; H01L 21/44

(52) U.S. Cl. 438/151; 438/678; 438/161

(57) ABSTRACT

A method for creating a source and a drain of a thin film transistor is disclosed. The method comprises the step (106) of forming a mask of a monolayer on a substrate. The mask will be used for selective electroless deposition of a metal layer (108). Thus, a metal layer could be grown in the areas where no monolayer is present. As a result, the grown metal layer could form a source and a drain with a gap in-between, where the monolayer has prevented deposition.

The present invention relates to a method for defining a source and a drain with a gap inbetween for thin film transistors. The method comprises the steps of depositing a first metal layer on a substrate, and forming a mask of a monolayer on top of the first metal layer by microcontact printing.

Improvements in the manufacturing of large-area electronics based on thin film structures is currently highly desired. The manufacture of large-area electronics, such as active-matrix liquid-crystal displays (AM-LCDs), is based on integrated circuit fabrication. However, the decreasing sizes of integrated circuits cannot be directly converted to lower costs for large-area electronics. Therefore, much effort is spent on developing new techniques for manufacturing of large-area electronics.

These large-area electronics are mostly based on combinations of transistors. Thus, manufacturing processes for simultaneous fabrication of transistors are of interest. In order to obtain sufficiently high switching speed with relatively low mobility semiconducting materials like polycrystalline Si, amorphous Si, or even organic semiconductors, it is important that a gap between a source and a drain in the transistor is held small.

Traditionally, photolithography is used for creating transistor structures. However, for large-area electronics this technique becomes very expensive and alternative techniques are therefore of interest.

Some new techniques for manufacturing of thin film transistors are presently being developed. In Y. Xia and G. M. Whitesides: Soft Lithography (Angew. Chem. Int. Ed. 1998, 37, 550-575), a new technique for defining a mask or pattern of a self-assembled monolayer (SAM) on a surface is presented. The technique is called microcontact printing. The general idea of microcontact printing is to contact a surface with a stamp, which has protruding elements and which is soaked with monolayer-forming molecules. When the surface is contacted by the stamp a monolayer is formed on the surface in the contact areas. Thus, a mask could easily be formed on the surface. This mask of SAM could then be used for preventing etching of an underlying layer in the areas that are covered by the mask. Thus, a desired pattern of a transistor or large-area electronic device could be formed by the selective etching. However, this technique has the disadvantage that a lot of material is wasted in the etching process. More importantly though, the selectivity of the mask of a SAM will not be good enough for direct etching of a layer of a few 100 nm's. In the required etching time, the monolayers will be attacked and holes will be etched in the patterns which should remain.

The article of Xia and Whitesides also presents a selective chemical vapor deposition (CVD) on a substrate with printed SAMs, cf. p. 561. However, CVD is a process in which special (usually highly poisonous) gaseous metallorganic compounds are decomposed on a surface to result in a metallic layer. This requires also a vacuum or reduced pressure process making it relatively expensive.

It is an object of the invention to provide a method for defining a source and a drain with a gap inbetween by printing techniques.

The object of the invention is accomplished by means of a method according to claim 1.

Thus, a method for defining a source and a drain with a gap inbetween for thin film transistors is provided, which method comprises the steps of:

depositing a first metal layer on a substrate,
forming a mask of a monolayer on top of the first metal layer by microcontact printing,
depositing a second electroless metal layer, said second electroless metal layer selectively depositing on areas of the first metal layer that are not covered by the monolayer, and
removing the monolayer and the first metal layer at least in the areas that were covered by the monolayer.

Thanks to the invention, a substrate is provided on which selective deposition of a metal layer could be performed by means of electroless deposition, which is a simple and harmless process. Thus, no excessive etching and deposition creating much waste material is needed because the first layer can be very thin (of the order of 10-20 nm). Using the method, gaps of sizes down to 2 μm could be achieved between structures of relatively thick metal layers (˜1 μm). Thus, the manufacturing of thin film transistors for forming large-area electronics, such as AM-LCDs, is made cheap and simple.

The step of removing the monolayer and the first metal layer in the areas that were covered by the monolayer may be divided in two steps. In a first step, the monolayer is removed using any of several different methods described below. Then, in a second step, the first metal layer in the areas that were covered by the monolayer is etched back.

However, the removal of the monolayer may be integrated with the etching back of first metal layer if an etchant is used by which the monolayer is rapidly attacked. Then, the monolayer will rapidly be removed and the etchant will shortly after the etching has started begin to etch back the first metal layer in the areas that were covered by the monolayer. In this manner, the second metal layer is relatively affected less than the first metal layer. Thus, the etchant will only affect the second metal layer insignificantly, since the second metal layer is much thicker than the first metal layer.

Thus, a separate monolayer removal may be omitted if an etchant for the etching back of the first metal layer is used by which the monolayer is rapidly attacked. In other words, the separate monolayer removal may be omitted if there is no selectivity for the monolayer in such an etchant. For instance, an aqueous solution of KI/I₂ (potassium iodide and iodine) may be used as such an etchant.

The method according to claim 2 is advantageous in that the patterned contact controls the pattern of the mask. The protruding elements of the stamp could thus be designed in accordance with the desired pattern of the mask.

By means of the method according to claim 3, the contact between the stamp and the first metal layer will transfer monolayer forming molecules from the stamp to the first metal layer.

The use of octadecylthiol as monolayer material in accordance with claim 4 is suitable in that octadecylthiol will bind to the first metal layer and form a monolayer. Furthermore, octadecylthiol is suitable for preventing deposition of metal. Thus a mask of octadecylthiol will form a pattern for selective deposition, but many other thiol molecules are possible, such as eicosanethiol, hexadecanethiol, etc.

The method according to claim 5 has the advantage that it enables patterning of the first metal layer before the use of the monolayer.

The use of silver or copper according to claim 6 as the metal for deposition is convenient in that silver and copper are suitable metals for use in electronic devices. Furthermore, silver and copper are not very expensive, which makes a device manufactured by the method cheap.

The method as defined in claim 7 or alternatively as defined in claim 8, 9 or 10 enables removal of the monolayer. The monolayer could either be removed by heating, which is a very simple step, or by argon-plasma treatment, which is not as simple as heating, but considerably faster.

The monolayer could also be removed by reductive desorption in aqueous KOH (e.g. in 0.5 M KOH) at about −1 V vs NHE (normalised hydrogen electrode); see e.g. “Influence of Surface Topography on Alkanethiol SAMs Assembled from Solution and by Microcontact Printing”, D. Losic, J. G. Shapter, and J. J. Gooding (Langmuir; 2001; 17(11); 3307-3316). Alternatively, the monolayer could be removed by heating the substrate for some time in organic solvents at an elevated temperature, e.g. cyclohexane close to the boiling point.

Suitably, a passivation layer is deposited on the structure when the source and drain have been created. Thus, the electrical stability of the device is ensured. These and other aspects of the invention will be apparent from and elucidated with reference to the embodiment described hereinafter.

A preferred embodiment of the invention will now be described with reference to the accompanying drawings, on which:

FIGS. 1 and 3-5 are sectional views of a substrate during different steps of growth of a source and a drain according to the inventive method.

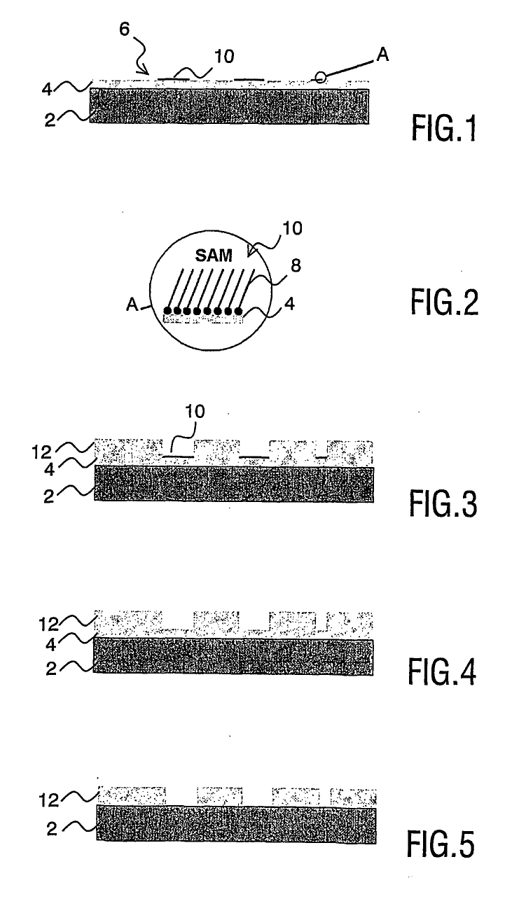

FIG. 2 is a sectional view of the area A in FIG. 1 in an enlarged scale.

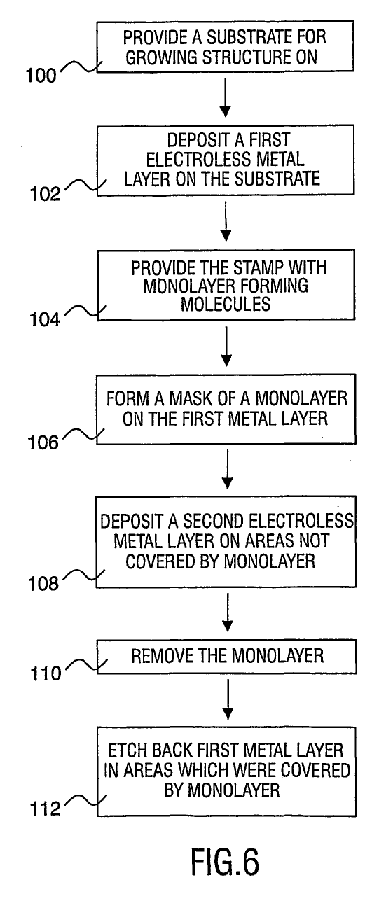

FIG. 6 is a flow chart of the method according to the invention.

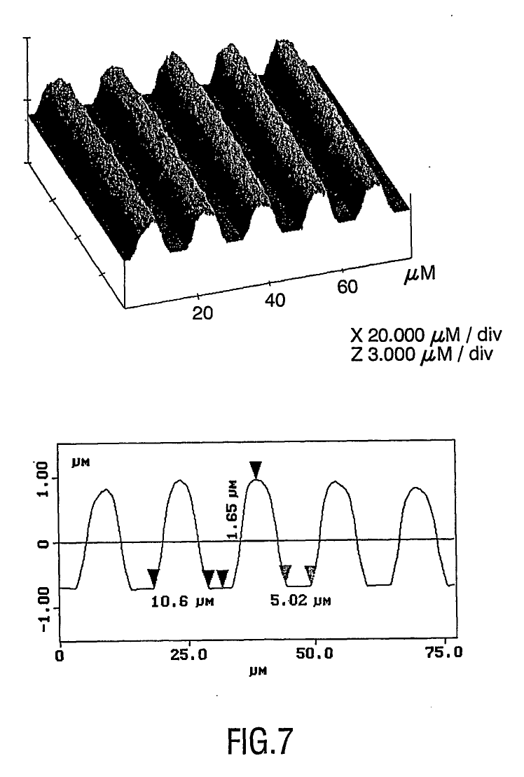

FIG. 7 is AFM-image of a structure grown in accordance with the method according to the invention.

Referring to FIGS. 1-5 and 6 a method according to the invention will now be described. In FIGS. 1-5, a substrate 2 is shown during different stages of a process of producing a source and a drain on the substrate 2. In FIG. 6, a flow chart of the process is shown. First, a substrate 2 is provided, step 100. Suitable substrates 2 are for instance glass, polymers, or composites, but also Si, GaAs or quartz can be used. Then, a first metal layer 4 is deposited on the substrate 4, step 102. Preferably, this metal layer is constituted of a thin layer of 2-20 nm of a base metal or alloy like Ti, TiW, Mo, or Cr, and 20 nm silver. Depending on the metal used in a second electroless metal layer, alternative materials which could be used for the metal of the first metal layer are for instance Pd, or Au. However, it is preferred that the first metal layer consists of the same metal as the second metal layer, since it is desired that an etching will be performed with the same speed in the first and the second metal layer. The first metal layer could be deposited by electroless deposition, high vacuum (<10⁻⁶ mbar) evaporation, or sputtering.

Then, a mask 6 of a monolayer is formed on the first metal layer 4 by microcontact printing, step 106, cf. FIG. 1. The mask 6 is formed by establishing contact between a stamp (not shown), which is provided with monolayer forming molecules, and the first metal layer 4 on the substrate 2.

The stamp is created in accordance with the following. First, a master is created. A wafer of Si(100) with a diameter of 6 inches is coated with a layer (˜150 nm) of Si₃N₄. This layer is deposited in a low pressure chemical vapor deposition (LPCVD) process by means of SiH₂Cl₂— and NH₃-gas at a temperature of approximately 800° C. A thin layer of positive photoresist is provided on this wafer by means of spin-coating. After UV irradiation through a mask and a developing step, a photoresist pattern is obtained on the wafer. The exposed Si₃N₄ is then etched by means of a CHF₃/O₂-plasma. During the etching the temperature remains below 100° C. The photoresist is removed by means of an oxygen plasma. The resulting Si₃N₄-pattern is used as an etch mask in reactive ion etching of the Si(100). After another oxygen plasma treatment the wafer is introduced in a desiccator together with approximately 0.5 ml of (heptadecafluoro-1,1,2,2-tetrahydrodecyl)trichlorosilane. The desiccator is pumped down to a pressure of approximately 0.2 mbar. After 60 minutes, the desiccator is vented and the wafer is placed in a preheated oven (100° C.) for one hour. Then, the master for the stamp is ready for use in creation of stamps.

The stamp is then created as the negative of the master. The negative of the master is made from Sylgard® 184 silicone rubber, produced by Dow Corning Corporation. 22 g of Sylgard® 184 “base” and 2.2 g of Sylgard® 184 “curing agent” are thoroughly mixed by stirring in, a polystyrene disposable holder. Air bubbles enclosed as a result of this are removed by placing the polystyrene holder in a desiccator and pumping down (in stages) to a pressure of 0.2 mbar. The Si-master wafer is placed on a vacuum chuck and the silicone mixture is gently poured over the master. A 100 μm thick polycarbonate sheet (3M Corp.) is mounted on the bottom part of a flat lid in the vacuum chuck. The lid is carefully lowered onto the silicone to a height of about 1 mm above the surface of the master. After curing at a temperature of 65° C. for 16 hours, the lid is opened and the polycarbonate sheet and stamp are peeled off from the master. The stamp is peeled off the polycarbonate sheet and is cut into pieces of 1-2 cm².

Before the microcontact printing, the stamp needs to be provided with monolayer forming molecules, step 104. Thus, the stamp, which is a piece of 1-2 cm², is inked by soaking it for 1-2 hours in a fresh 2 mM solution of octadecylthiol in ethanol. After removal from the solution the stamp is rinsed with ethanol and dried in a stream of nitrogen gas. Then, octadecylthiol will be provided in the stamp. The printing face of the stamp is then brought into contact with the surface of the substrate during step 106 and is removed in about 15 seconds. In this process a self-assembled monolayer (SAM; thickness ˜2 nm) of octadecylthiol is produced on the surface of the first metal layer, cf. FIG. 2). Each molecule 8 spontaneously bind to the metal surface 4. Thus, a compact monolayer 10 is formed of adjacent molecules 8.

After removal of the stamp, an electroless deposition, step 108, is applied in which electroless growth is limited to the areas which do not contain the monolayer 10, in particular a gap between a source and a drain. In this step, a second electroless metal layer 12 with a thickness of about 500 nm is deposited. In this step, the substrate 2 is immersed in an electroless silver bath on the basis of an ammoniacal silver solution and a reduction agent. This bath is described in example 6 of U.S. Pat. No. 3,960,564. After a certain time the substrate 2 is removed from this solution and rinsed with deionized water and dried in a stream of nitrogen gas. Inspection by optical microscopy, atomic force microscopy or scanning electron microscopy shows that silver deposition only occurs in the areas which have not been contacted by the stamp in the printing step 106, cf. FIG. 3. The thickness of the resulting pattern depends on the deposition time (15 minutes-4 hours) and temperature of the solution.

Finally, the very thin silver film (20 nm) between the deposited silver of the second metal layer is removed by etching. First the SAM is removed, step 110, cf. FIG. 4, by either heating the substrate 2 to about 100-150° C. for a period of time (a few minutes to several hours) or by Ar-plasma treatment at a pressure of 0.2 mbar and a power of 300 W at a discharge frequency of 2.45 GHz for 5-10 minutes. The Ar-plasma treatment could be performed using TePla 300 E of TePla Inc. The monolayer can also be removed by reductive desorption in aqueous KOH (e.g. in 0.5 M KOH) at about −1 V vs NHE. Alternatively, the monolayer could also be removed by heating the substrate for some time in organic solvents at an elevated temperature (e.g. in cyclohexane close to the boiling point).

The substrate 2 is then immersed in an aqueous etching solution containing 0.1 M K₂S₂O₃ and 0.01 M K₃Fe(CN)₆ for 10 seconds. By this treatment also a small part of the deposited silver film of the second metal layer is removed, cf. FIG. 5. Thus, the first metal layer 4 is removed in the areas, where deposition of the second metal layer 12 was not allowed by the mask 6, step 112.

Subsequently, the passivation layer could be applied. To ensure good contact between the drain and a pixel electrode another electroless step could be carried out to at least partially fill the contact hole with metal.

Referring now to FIG. 7, an AFM-image of a substrate is shown, on which selective deposition of a metal layer has been performed according to the method described above. Here, gaps are shown between areas of deposited metal, which could correspond to a source and a drain with a gap in-between. From this image it is clear that layers of 1.65 μm in height has been grown with gaps of down to 5 μm between them.

Thanks to the invention selective electroless deposition of a metal layer could be performed for forming a gap between a source and a drain. The inventive method might not achieve the same resolution as could be achieved by photolithographic methods, but the inventive method is much cheaper and resolutions sufficient for large-area electronics are achievable. Thus, a vast improvement for manufacturing processes for large-area electronics is disclosed.

It should be emphasized that the preferred embodiments described herein is in no way limiting and that many alternative embodiments are possible within the scope of protection defined by the appended claims. For example, other stamp materials could be used, such as other types of silicone or polyurethane rubber. Furthermore, the method could be used for manufacturing other devices like “electronic paper”, cheap rf-labeling tags or tunable optical fiber devices.

Also, a relatively coarse pattern could be created already when the first metal layer is deposited. This could be achieved by using a printed sensitizer as catalyst. An example of a process of printing a sensitizer can be found in H. Kind, M. Geissler, H. Schmid, B. Michel, K. Kern, and E. Delamarche: “Patterned Electroless Deposition of Copper by Microcontact Printing Palladium(II) Complexes on Titanium-Covered Surfaces”, Langmuir; 2001; 16(16); 6367-6373. Alternatively, a silver containing solution, e.g. colloidal silver particles in an organic solvent, may be coarsely patterned by inkjet printing or other printing techniques like offset printing.

1. A method for defining a source and a drain with a gap inbetween for thin film transistors, comprising the steps of:
depositing a first metal layer on a substrate, forming a mask of a monolayer on top of the first metal layer by microcontact printing,
depositing a second electroless metal layer, said second electroless metal layer selectively depositing on areas of the first metal layer that are not covered by the monolayer, and
removing the monolayer and the first metal layer at least in the areas that were covered by the monolayer.

2. The method according to claim 1, wherein the step of forming a mask of a monolayer comprises the step of transferring monolayer forming molecules from a stamp to the first metal layer by establishing a patterned contact between the first layer and the stamp by means of the stamp having protruding elements.

3. The method according to claim 2, wherein the step of forming a mask of a monolayer comprises the step of providing the stamp with monolayer forming molecules.

4. The method according to claim 3, wherein the step of providing a surface of the stamp with monolayer forming molecules comprises providing the surface of the stamp with octadecylthiol, which will form the monolayer.

5. The method according to claim 1, wherein the step of depositing the first metal layer comprises the step of forming a patterned layer by using a printed sensitizer as catalyst.

6. The method according to claim 1, wherein the steps of depositing metal layers comprises the step of depositing silver or copper.

7. The method according to claim 1, wherein the step of removing the monolayer comprises the step of heating the structure.

8. The method according to claim 1, wherein the step of removing the monolayer comprises the step of argon-plasma treatment.

9. The method according to claim 1, wherein the step of removing the monolayer comprises reductive desorption.

10. The method according to claim 1, wherein the step of removing the monolayer comprises the step of heating the substrate in organic solvents at an elevated temperature.

11. The method according to claim 1, further comprising the step of depositing the structure with a passivation layer when the source and drain have been created.
